(19) United States
(12) Patent Application Publication
(10) Pub. No.: US 2014/0002086 A1
(43) Pub. Date: Jan. 2, 2014

(54) Local Coils

(71) Applicants: Patrick Gross, Buckenhof (DE); Björn Heismann, Erlangen (DE)

(72) Inventors: Patrick Gross, Buckenhof (DE); Björn Heismann, Erlangen (DE)

(21) Appl. No.: 13/930,443

(22) Filed: Jun. 28, 2013

(30) Foreign Application Priority Data
Jun. 29, 2012 (DE) DE 102012211269.3

(51) Int. Cl. G01R 33/341

(52) U.S. Cl. CPC G01R 33/341
USPC 324/322

(57) ABSTRACT

A magnetic resonance tomography (MRT) local coil for an MRT device includes an antenna that includes a plurality of conductor elements that run in parallel to one another on a transparent carrier.

### RELATED APPLICATIONS

This application claims the benefit of German Patent Application No. DE 102012211269.3, filed Jun. 29, 2012, the entire contents of which are hereby incorporated herein by reference.

### TECHNICAL FIELD

The present teachings relate generally to a magnetic resonance tomography (MRT) local coil for a magnetic resonance device.

### BACKGROUND

Magnetic resonance devices (MRTs), such as those described in DE10314215B4, are used to examine objects or patients by magnetic resonance tomography.

### SUMMARY AND DESCRIPTION

The scope of the present invention is defined solely by the appended claims, and is not affected to any degree by the statements within this summary.

The present embodiments may obviate one or more of the drawbacks or limitations in the related art. For example, in some embodiments, optimized MRT local coils are provided.

### BRIEF DESCRIPTION OF THE DRAWINGS

FIG. 1 shows a rectangular conductor of an antenna of an MRT local coil on a conventional mechanical carrier structure.

FIG. 2 shows a cross-section of an exemplary first embodiment of an antenna of an MRT local coil with a plurality of conductor elements running in parallel to one another on one side of a transparent carrier.

FIG. 3 shows a cross-section of an exemplary second embodiment of an antenna of an MRT local coil with a plurality of conductor elements running in parallel to one another on two opposing sides of a transparent carrier.

FIG. 4 shows a cross-section of an exemplary third embodiment of an antenna of an MRT local coil with substantially circular conductor elements run in parallel to one another on two opposing sides of a transparent carrier.

FIG. 5 shows a top plan view of an exemplary embodiment of antennae of an MRT local coil with a plurality of conductor elements running in parallel to one another on a side of a transparent carrier installed in a non-transparent carrier, and capacitors that connect the conductor elements.

FIG. 6 shows a longitudinal cross-section of an exemplary embodiment of an antenna in a head coil.

FIG. 7 shows a schematic representation of an exemplary MRT system.

### DETAILED DESCRIPTION

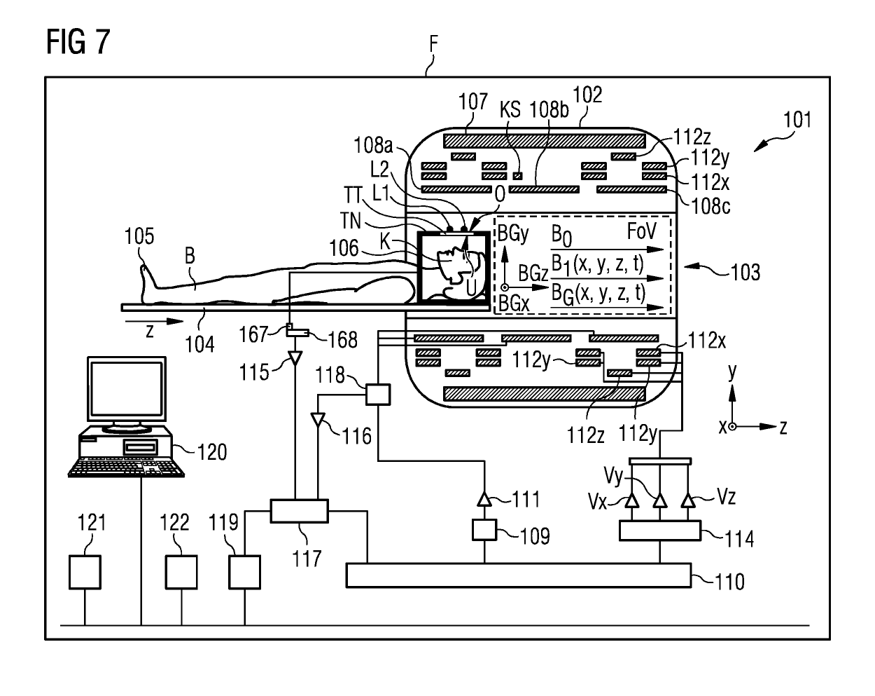

FIG. 7 shows an imaging magnetic resonance device MRT 101 disposed in a shielded room or Faraday cage F. The MRT 101 includes a whole body coil 102 with a tubular space 103. A patient couch 104 with a body of an examination object, such as a patient 105, may be moved in the direction of arrow z in order to generate recordings of the patient 105 by an imaging method. The patient couch 104 may or may not include local coil arrangement 106. In some embodiments, as shown in FIG. 7, a local coil arrangement 106 with a plurality of antennae is arranged on the patient. Recordings of a subarea of the body 105 in the field of view (FOV) may be generated in a local area of the MRT 101. Signals of the local coil arrangement 106 may be evaluated (e.g., converted into images, stored or displayed) by an evaluation device (e.g., including elements 168, 115, 117, 119, 120, 121, etc.) of the MRT 101. The evaluation device may be connected to the local coil arrangement 106 wirelessly 167, by coaxial cables, or the like.

To examine a body 105 (e.g., an examination object or a patient) with magnetic resonance imaging using a magnetic resonance device MRT 101, various magnetic fields are irradiated onto the body 105. The various magnetic fields are attuned as accurately as possible to one another in terms of temporal and spatial characteristics. A strong magnet (e.g., a cryomagnet 107) in a measuring cabin with a tunnel-shaped opening 103 may be used to generate a strong static main magnetic field B₀ (e.g., 0.2 Tesla to 3 Tesla or higher). A body 105 to be examined may be mounted on a patient couch 104 in a substantially homogenous region of the main magnetic field BO when viewed in the FOV. Excitation of the nuclear spin of atomic nuclei of the body 105 is achieved by magnetic high frequency excitation pulses B1(x, y, z, t) that are irradiated via a high frequency antenna and/or, optionally, a local coil arrangement if needed. The high frequency antenna is shown in simplified form in FIG. 7 as a body coil 108 (e.g., a multipart body coil 108a, 108b, 108c). In some embodiments, high frequency excitation pulses are generated by a pulse generation unit 109 that is controlled by a pulse sequence control unit 110. After amplification by a high frequency amplifier 111, the high frequency excitation pulses are routed to the high frequency antenna 108. The high frequency system is shown schematically in FIG. 7. In some embodiments, a magnetic resonance device 101 includes more than one pulse generation unit 109, more than one high frequency amplifier 111, and a plurality of high frequency antennae 108a, 108b, 108c.

The magnetic resonance device 101 further includes gradient coils 112x, 112y, 112z, which provide magnetic gradient fields B_{G}(x, y, z, t) for selective slice excitation and local encoding of a measuring signal during a measurement. The gradient coils 112x, 112y, 112z are controlled by a gradient coil control unit 114 that, similarly to the pulse generation unit 109, is connected to the pulse sequence control unit 110.

Signals emitted by the excited nuclear spin of the atomic nuclei in the examination object are received by the body coil 108 and/or by at least one local coil arrangement 106. The received signals are amplified by assigned high frequency amplifier 116 and further processed and digitized by a receive unit 117. The recorded measuring data are digitized and stored as complex numerical values in a k-space matrix. An associated MR image may be reconstructed from the k-space matrix populated with values by a multi-dimensional Fourier transformation.

The correct signal forwarding for a coil (e.g., body coil 108 or local coil 106) that may be operated both in transmit and receive mode is controlled by an upstream transmit-receive switch 118.

An image processing unit 119 generates an image from the measuring data. The image is shown to a user via a control console 120 and/or is stored in a storage unit 121. A central computing unit 122 controls the individual system components.

In MR tomography, images with a high signal-to-noise ratio (SNR) may be recorded using local coil arrangements (e.g., Coils, Local Coils). The local coil arrangements are antenna systems that are, for example, attached in direct vicinity, on (anterior), below (posterior), at, or in—the body 105. With an MR measurement, the excited nuclei induce a voltage in the individual antennae of the local coil. The induced voltage is then amplified with a low-noise preamplifier (e.g., LNA, Preamp) and forwarded to the receive electronics. In order to improve the signal-to-noise ratio even with highly-resolved images, high field systems (e.g., 1.5 T-12 T or higher) may be used. If more individual antennae are connected to an MR receive system than there are receivers present, a switching matrix (e.g., RCCS) may be integrated between the receive antennae and the receivers. The switching matrix routes the currently active receive channels (e.g., the receive channels that lie in the FOV of the magnet) to the existing receiver. It is thus possible to exclude more coil elements than there are receivers present. With whole body coverage, only those coils disposed in the FOV and/or in the homogeneity volume of the magnet are read out.

An antenna system may be referred to as a local coil arrangement 106. In some embodiments, the antenna system may include an antenna element or an array coil including a plurality of antenna elements (e.g., coil elements). In some embodiments, the individual antenna elements are provided as loop antennae (e.g., loops), butterfly coils, flexible coils, or saddle coils. In some embodiments, a local coil arrangement includes coil elements, a preamplifier, further electronics (e.g., decoupling coils, etc.), a housing, contacts, and may include a cable with a plug (e.g., for connection to the MRT system). A receiver 168 attached on the system side filters and digitizes a signal received from a local coil 106 (e.g., by radio) and transfers the data to a digital signal processing device. The digital signal processing device may derive an image or a spectrum from the data obtained through measurement, and provide the image or spectrum to a user for subsequent diagnosis or storage.

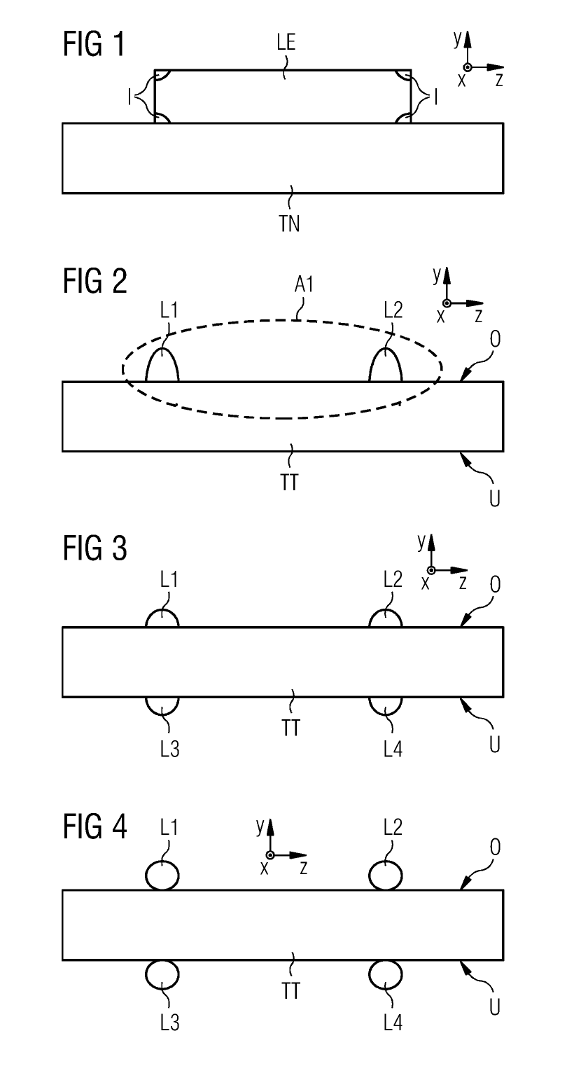

FIG. 1 shows a rectangular conductor of an antenna of an MRT local coil on a conventional mechanical carrier structure (e.g., carrier).

MRT local coils may be constructed with relatively wide antenna conductor elements in order to prevent RF conduction problems. When used in an MRT local coil in the form of an MRT head coil, these conductor elements are not optimally transparent, which results in a limited view for the patient wearing the helmet-like MRT head coil during the MRT examination. The less-than-optimum transparency of the conductor elements may result in a suboptimal design from an RF point of view (e.g., radio frequency view or high frequency view).

In a birdcage-type design, gaps along the head-to-foot direction may run between conductor elements, thereby allowing a patient to see between conductor elements. Alternatively, conductor elements of the antennae may be arranged in a head coil such that the patient may see between the conductor element loops. In view of eddy currents, slotted copper tracks (e.g., copper conductor element paths) may be used. In order to minimize capacitance, conductor paths may be increased (e.g., maximally by the distance between the equivalent capacitor), narrowed, or provided with a “hole” in the copper in the center of the conductor path, thereby minimizing the area with copper in the overlap.

If RF currents are observed on a conductor element, the theory that electrons evenly traverse the conductor element to the characteristic RF surface depth across the cross-section of the conductor path only applies to conductor elements with a circular cross-section.

For conductor elements with an approximately rectangular cross-section (e.g., copper tracks or copper paths), the currents run into the corners of the conductor element. This may be due to electron repulsion, which may cause the electrons to flow such that the distances between them are maximized. The RF performance (e.g., the RF or HF behavior) of a thin rectangular conductor element may be approximated by replacing the conductor element with four conductors on the corners of a rectangular cross-section with an occasional balancing of potential along the length of the conductor element.

In some embodiments, a parallel configuration of thinner (as compared to the conventional conductor element LE) conductor elements L1, L2 and/or L1, L2, L3, L4 may be used (e.g., on the surface of or in a carrier TT).

The thinner conductor elements may be arranged, for example, in the previous area of the corners or edges of a conventional conductor element LE (e.g., in the form of two small conductor elements (L1, L2). The conductor elements may be arranged either according to FIG. 1 (e.g., on just one side O of a transparent area TT) or FIG. 3 (e.g., on two sides O, U of a transparent area TT). In some embodiments, the conductor elements may be connected to one another outside of the transparent area TT and run further only as a single-path conductor element (e.g., to an evaluation device or amplifier).

In some embodiments, a transparent carrier (e.g., a see-through carrier TT) may be used as a mechanical carrier.

Different configurations are possible. In some embodiments, the conductor paths L1-L10 running in parallel with one another may be sprayed or wet-etched on a substrate. In some embodiments, the substrate may be transparent glass or a transparent circuit board (e.g., conductor board) material or indium tin oxide sheets (e.g., ITO layers).

In some embodiments, thin wires may be embedded as conductor elements L1-L10 in a 3-dimensional transparent polymer matrix.

In some embodiments, laser sintering or stereolithography may be used to form an arrangement made of metal and transparent structures.

In some embodiments, an arrangement that is transparent in a region TT is provided. In some embodiments, an MRT head coil 106 may optimize the view of a patient disposed with his or her head K therein. In some embodiments, additional options may be integrated into the arrangement (e.g., audio-visual equipment or optical lenses).

In accordance with the present teachings, current may not flow over an entire conventional conductor LE. For example, only the subareas of a conventional structure may be provided with a conductive material (e.g., copper) in which current flows. Adequate/regular balancing of potentials may be provided between the sub tracks (e.g., conductor elements).

In some embodiments, interferences with gradient fields may be reduced. In some embodiments, this reduction in interferences may result in a reduction in acoustic noise and capacitances in overlapping coil arrays.

FIG. 1 shows currents I in a conventional, rectangular conductor LE on a conventional mechanical carrier TN.

In some embodiments of a conductor element arrangement according to FIGS. 2-7, the conventional, rectangular conductor path structure LE may be provided with two, four, or more narrow conductor element structures L1-L10 (sub tracks). Alternatively, or in addition, the carrier structure TT may be wholly or partially transparent (e.g., see-through) in some embodiments.

In some embodiments, as shown in FIG. 3, conductor elements may be provided with conductor path elements on both sides of a transparent carrier (e.g, “sub tracks”). This configuration may increase distances between flowing electrons and, as a result, increase the effective surface through which currents I flow. In addition, the resistance may be reduced if necessary.

A “window” (e.g., a see-through or transparent region TT) on or in which see-through conductor elements (e.g., paths, tracks, sub tracks) are integrated may, in some embodiments, be integrated in a conventional, non-transparent (e.g., non-see-through) structure TN.

Conductor elements L1-L10 may be connected to capacitances. The capacitances may, if necessary, be connected to, for example, amplifiers, evaluation devices, signal transmission devices, or the like. As a result, a balancing of the potentials of each conductor element L1-L10 may be achieved.

Sub tracks (e.g., conductor elements L1-L10) may be provided as thin round wires. Since these structures may have a rather soft surface (e.g., few or no corners), the conductivity may be further optimized.

A see-through window in region TT may be combined with further optical elements and/or display systems in order to further increase patient comfort. It is to be understood, however, that the present teachings are not restricted to head coils. By way of example, transparency may also be used for paediatric local coils or coils for research purposes (e.g., “multi-modality”) in combination with optical imaging.

FIG. 2 shows a cross-sectional view of an exemplary antenna Al of an MRT local coil that includes two conductor elements L1, L2 running parallel to one another on a side O of a transparent carrier TT.

FIG. 3 shows a cross-sectional view of an exemplary antenna A1 of an MRT local coil 106 that includes a plurality of conductor elements L1, L2 and L3, L4. The plurality of conductor elements L1, L2 and L3, L4 have substantially semicircular cross-sections and run parallel along two opposing sides O, U of a transparent carrier TT.

FIG. 4 shows a cross-section of an exemplary antenna A1 of an MRT local coil 106 that includes a plurality of conductor elements L1, L2 and L3, L4 having circular or elliptical cross-sections and that run parallel to one another on two opposing sides O, U of a transparent carrier TT.

FIG. 5 shows a top view of exemplary antennae A1, A2, A3, A4 of an MRT local coil. Each of the antennae has a plurality of conductor elements L1, L2; L3, L4; L5, L6; L7, L8; L9, L10, and capacitors Ko1, Ko2, Ko3, Ko4, Ko5, Ko6, Ko7, Ko8. The capacitors proceed in parallel to one another on a side O of a transparent carrier (T) (e.g., integrated in a non-transparent region TN thereof). The antennae A1, A2, A3, A4 are connected by the conductor elements L1, L2; L3, L4; L5, L6; L7, L8; L9, L10 running in pairs on the transparent carrier TT.

In some embodiments, the carrier TT may be arranged in a viewing area window TT in front of a patient wearing a head coil 106 on his or her head.

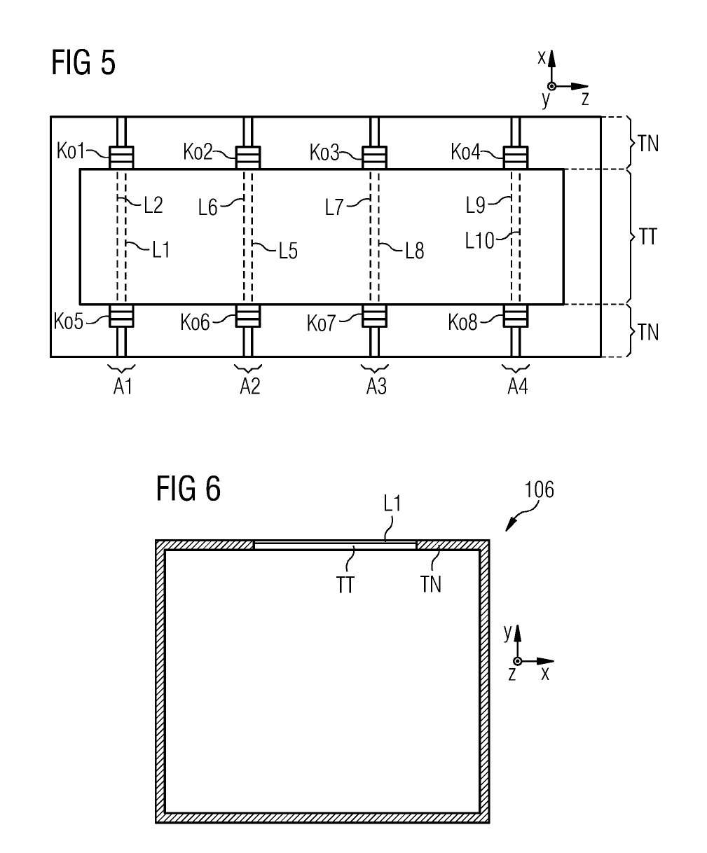

FIG. 6 shows a longitudinal section of a head coil 106 in which conductor elements L1 deeply embedded (or, in some embodiments, resting) in this region may be provided in a transparent region TT.

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding claim—whether independent or dependent—and that such new combinations are to be understood as forming a part of the present specification.

1. A magnetic resonance tomography (MRT) local coil for an MRT device, the MRT local coil comprising:
an antenna comprising a plurality of conductor elements, wherein the plurality of conductor elements run in parallel to one another on a transparent carrier.

2. The MRT local coil of claim 1, wherein conductor elements of the plurality of conductor elements run in parallel to one another on two opposing sides of the transparent carrier.

3. The MRT local coil of claim 1, wherein at least two conductor elements of the plurality of conductor elements run in parallel to one another only on one side of the transparent carrier.

4. The MRT local coil of claim 2, wherein the plurality of conductor elements are substantially circular in cross section.

5. The MRT local coil of claim 1, further comprising a head coil.

6. The MRT local coil of claim 2, further comprising a head coil.

7. The MRT local coil of claim 3, further comprising a head coil.

8. The MRT local coil of claim 4, further comprising a head coil.

9. The MRT local coil of claim 1, wherein each conductor element of the plurality of conductor elements is connected individually or in multiples to at least one capacitor.

10. The MRT local coil of claim 2, wherein each conductor element of the plurality of conductor elements is connected individually or in multiples to at least one capacitor.

11. The MRT local coil of claim 3, wherein each conductor element of the plurality of conductor elements is connected individually or in multiples to at least one capacitor.

12. The MRT local coil of claim 1, further comprising a plurality of antennae, the plurality of antennae comprising the antenna, each antenna of the plurality of antennae comprising a plurality of conductor elements running in parallel to one another on the transparent carrier.

13. The MRT local coil of claim 12, wherein the plurality of conductor elements of the plurality of antennae run in parallel on two opposing sides of the transparent carrier.

14. The MRT local coil of claim 12, wherein the plurality of conductor elements of the plurality of antennae run in parallel on only one side of the transparent carrier.

15. The MRT local coil of claim 1, wherein the plurality of conductor elements comprises a total of two conductor elements.

16. The MRT local coil of claim 1, wherein the plurality of conductor elements comprises a total of four conductor elements.

17. The MRT local coil of claim 1, wherein the plurality of conductor elements are configured along conductor paths that are sprayed or wet-etched onto a substrate.

18. The MRT local coil of claim 1, wherein the plurality of conductor elements are configured along conductor paths that are applied to a substrate as transparent glass, a transparent conductor plate material, or an indium tin oxide layer.

19. The MRT local coil of claim 1, wherein the plurality of conductor elements are embedded as wires in a three-dimensional transparent polymer matrix.

20. The MRT local coil of claim 1, wherein the plurality of conductor elements are arranged on a transparent structure by laser sintering or stereolithography.
